(19) United States
(12) Patent Application Publication
(10) Pub. No.: US 2026/0018499 A1
(43) Pub. Date: Jan. 15, 2026

(54) SEMICONDUCTOR DEVICE, BATTERY MODULE, ELECTRIC POWER MODULE, AND ELECTRIC VEHICLE

(71) Applicant: ROHM CO., LTD., Kyoto-shi (JP)

(72) Inventors: Akio SASABE, Kyoto-shi (JP); Daiki YANAGISHIMA, Kyoto-shi (JP); Sho TANAKA, Kyoto-shi (JP); Yoshizo OSUMI, Kyoto-shi (JP); Ryohei UMENO, Kyoto-shi (JP)

(21) Appl. No.: 19/338,177

(22) Filed: Sep. 24, 2025

Related U.S. Application Data
(63) Continuation of application No. PCT/JP2024/011732, filed on Mar. 25, 2024.

(30) Foreign Application Priority Data
Mar. 29, 2023 (JP) 2023-052945

(51) Int. Cl. H01L 23/495; B60L 50/60; H01L 23/00; H01L 25/065; H10D 80/30; H10D 84/00

(52) U.S. Cl. CPC H01L 23/49575; B60L 50/60; H01L 23/49537; H01L 23/49593; H01L 24/48; H01L 25/0655; H10D 80/30; H10D 84/209; B60L 2210/12; B60L 2210/42; H01L 2224/48137; H01L 2224/48245

(57) ABSTRACT

A semiconductor device includes a low-voltage side frame configured to be connected to a low-voltage chip driven by an input voltage and connected to a ground potential; and a high-voltage side frame configured to be insulated from the low-voltage side frame and connected to a high-voltage chip supplied with a supply voltage having a higher voltage than the input voltage. The high-voltage side frame is connected to a reference potential.

### CROSS REFERENCE TO RELATED APPLICATIONS

This application is a continuation under 35 U.S.C. § 120 of PCT/JP2024/011732, filed Mar. 25, 2024, which is incorporated herein by reference, and which claimed priority to Japanese Application No. 2023-052945, filed Mar. 29, 2023. The present application likewise claims priority under 35 U.S.C. § 119 to Japanese Application No. 2023-052945, filed Mar. 29, 2023, the entire content of which is also incorporated herein by reference.

### TECHNICAL FIELD

The present invention relates to a semiconductor device and relates to a battery module including the semiconductor device, an electric power module using the battery module, and an electric vehicle using the electric power module.

### BACKGROUND ART

In a semiconductor package, a structure is known in which a plurality of chips are mounted on a common frame (for example, see Patent Document 1).

### LIST OF CITATIONS

### Patent Literature

Patent Document 1: JP-A-2019-169512

### BRIEF DESCRIPTION OF DRAWINGS

FIG. 1 is a schematic structural diagram of an electric vehicle.

FIG. 2 is a schematic layout diagram of a battery module viewed from above.

FIG. 3 is a structural diagram illustrating a schematic structure of a battery module.

FIG. 4 is a front cross-sectional view of the semiconductor device illustrated in FIG. 1.

FIG. 5 is a diagram illustrating a schematic structure of the semiconductor device of a modified example.

### DESCRIPTION OF EMBODIMENTS

In this specification, a metal oxide semiconductor (MOS) field-effect transistor means a transistor having a gate structure made of at least three layers, including a “layer made of a conductor or a semiconductor such as polysilicon having a small resistance value”, an “insulation layer”, and a “P-channel type, N-channel type, or intrinsic semiconductor layer”. In other words, the gate structure of the MOS field-effect transistor is not limited to a three-layer structure of metal, oxide, and semiconductor.

Hereinafter, an embodiment of the present invention is described with reference to the drawings. Note that in this specification, if it is written that elements are connected, the connection includes mechanical connection as well as electrical connection, i.e., a case where a current flowing state is realized. For this reason, “connecting” include a case of “electrically connecting”.

In addition, there is a case where a device is connected to an element or a terminal at a certain potential, so that electricity for driving the device can be obtained. In this case, it is described that the connected device is supplied with a voltage that is a potential difference between a reference potential given to the element or the terminal and a potential of the element.

### <Electric Vehicle A>

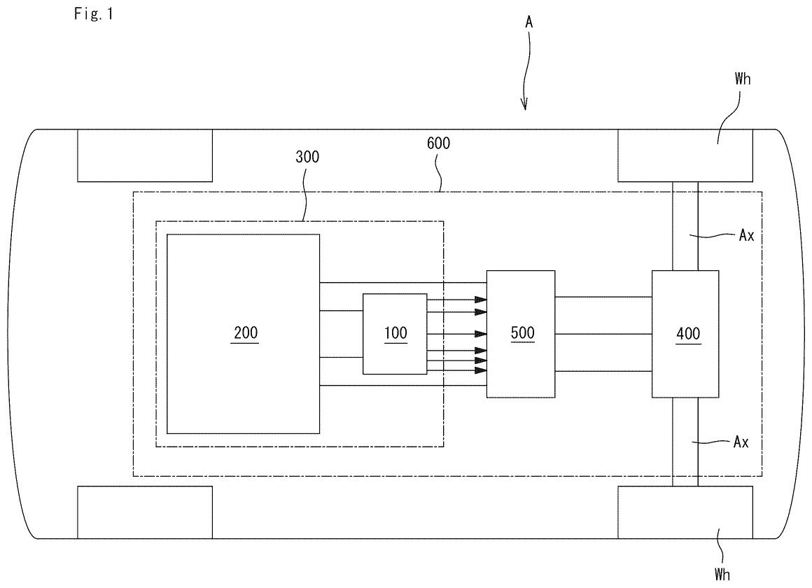

FIG. 1 is a schematic structural diagram of an electric vehicle A. In the electric vehicle A, an electric power module 600 is attached to an axle shaft Ax to which wheels Wh are attached. The electric power module 600 is configured to rotate the axle shaft Ax utilizing electric energy, so as to allow the electric vehicle A to run.

As illustrated in FIG. 1, the electric power module 600 includes a battery module 300, a motor 400, and a motor control unit (MCU) 500.

The motor 400 is an example of a drive source, and a not-shown rotation shaft is directly or indirectly connected to the axle shaft Ax. The electric vehicle A usually has a structure in which an AC motor is used as the motor 400. As a battery 200 is DC, the motor control unit 500 has a structure capable of converting DC current of the battery 200 into AC, which is supplied to the motor 400. In addition, the motor control unit 500 is configured to control the supply current so as to adjust the number of rotations, torque, and the like of the motor 400.

Note that also in a case where a DC motor is used as the motor 400, the motor control unit 500 is configured to control the number of rotations, torque, and the like of the motor 400.

### <Battery Module 300>

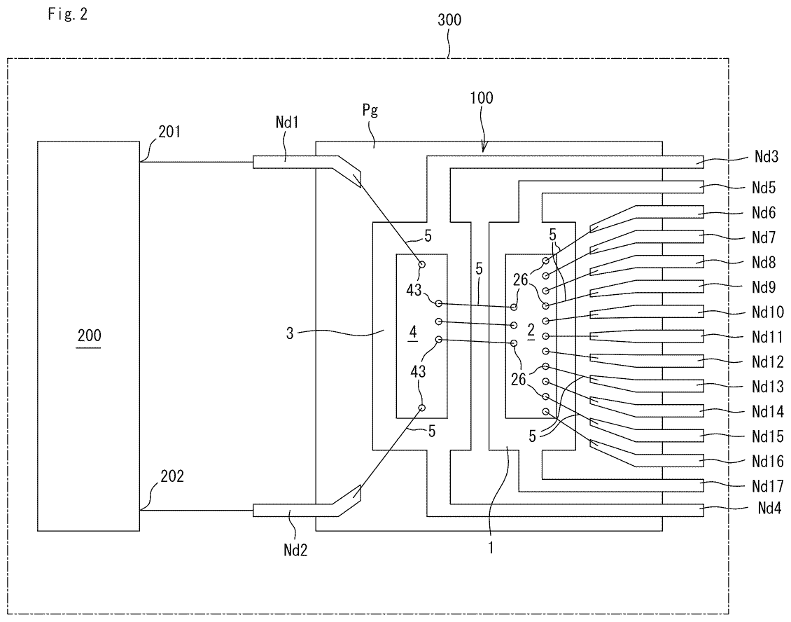

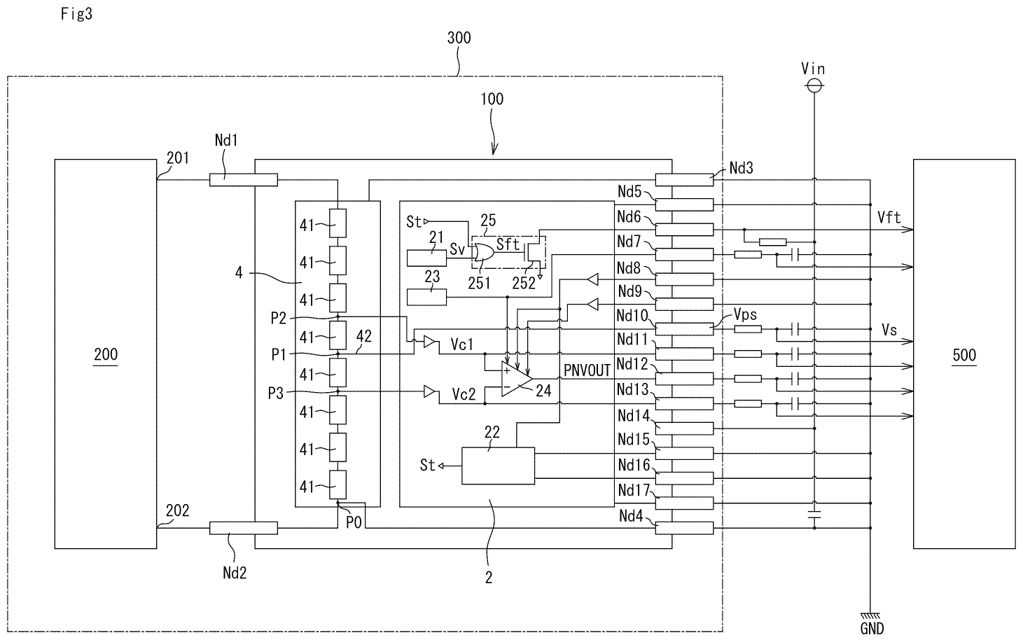

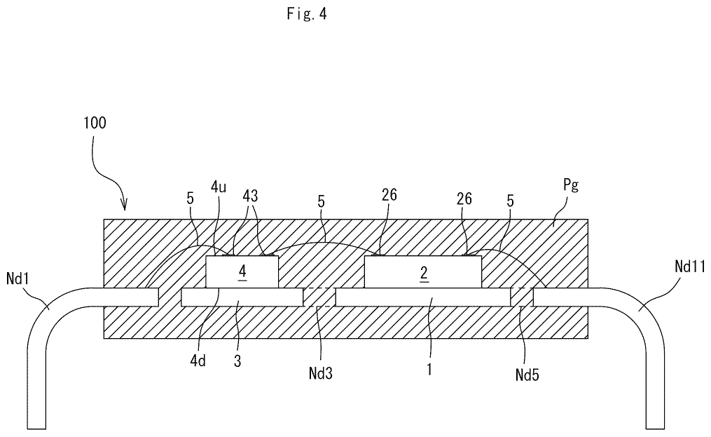

Next, details of the battery module 300 are described with reference to the drawings. FIG. 2 is a schematic layout diagram of the battery module 300 viewed from above. FIG. 3 is a structural diagram illustrating a schematic structure of the battery module 300. FIG. 4 is a front cross-sectional view of a semiconductor device 100 illustrated in FIG. 1. Note that in the cross-sectional view of the semiconductor device 100 illustrated in FIG. 4, for simple description, a connection terminal Nd1, a pad 26, a pad 43, and a wire 5, which are hidden in a package Pg, are shown in the same cross section.

The battery module 300 includes the semiconductor device 100 and the battery 200. The battery 200 generates a supply voltage having a high voltage such as 400 V, which is necessary for driving the motor 400. The battery module 300 is connected to the motor control unit 500.

In the electric vehicle A, the battery module 300 is connected to the motor control unit 500. The battery module 300 supplies the supply voltage from the battery 200 directly to the motor control unit 500. In addition, the supply voltage output from the battery 200 is stepped down to an operating voltage Vs such as 10 V, 5 V, or 3.3 V for driving a not-shown control circuit of the motor control unit 500, and supplies to the motor control unit 500.

As illustrated in FIG. 2 and FIG. 3, the battery 200 has a positive electrode 201 and a negative electrode 202. The battery 200 has a structure in which a potential of the positive electrode 201 is higher than a potential of the negative electrode 202 by the supply voltage. In other words, the potentials of the positive electrode 201 and the negative electrode 202 of the battery 200 vary depending on the connected circuit.

### <Semiconductor Device 100>

Next, a structure of the semiconductor device 100 is described. The semiconductor device 100 supplies the operating voltage Vs obtained by stepping down the supply voltage from the battery 200 to the motor control unit 500. In addition, the semiconductor device 100 has a structure in which a voltage other than the operating voltage Vs is also supplied to the motor control unit 500. The motor control unit 500 is driven by the operating voltage Vs supplied from the semiconductor device 100 and can determine a state of the battery module 300 on the basis of another voltage supplied from the semiconductor device 100.

As illustrated in FIG. 2 to FIG. 4, the semiconductor device 100 includes a low-voltage side frame 1, a low-voltage chip 2, a high-voltage side frame 3, a high-voltage chip 4, and the connection terminals Nd1 to Nd17. Further, as illustrated in FIG. 2 and FIG. 4, the low-voltage side frame 1, the low-voltage chip 2, the high-voltage side frame 3, and the high-voltage chip 4 of the semiconductor device 100 are sealed in the package Pg made of resin. In addition, a part of the connection terminal Nd1 to Nd17 is also sealed in the package Pg. In other words, the connection terminals Nd1 to Nd17 each have a part exposed to the outside of the package Pg. All the connection terminals Nd1 to Nd17 have conductively.

The high-voltage side frame 3 is made of a plate material having conductivity. As illustrated in FIG. 2, the connection terminal Nd3 and the connection terminal Nd4 are formed integrally with the high-voltage side frame 3. The high-voltage side frame 3 is connected to a ground potential GND via the connection terminal Nd3 and the connection terminal Nd4. Note that it may be possible to adopt a structure in which the connection terminal Nd3 and the connection terminal Nd4 are disposed apart from the high-voltage side frame 3, and the connection terminal Nd3 and the connection terminal Nd4 are each connected to the high-voltage side frame 3 by wire. As long as the connection terminal Nd3 and the connection terminal Nd4 are securely connected to the high-voltage side frame 3, the connection method is not limited.

The connection terminal Nd1 and the connection terminal Nd2 are respectively connected to the positive electrode 201 and the negative electrode 202 of the battery 200. The connection terminal Nd1 and the connection terminal Nd2 are each connected to the high-voltage chip 4, which is connected to the high-voltage frame 3, via the wire 5 having conductivity. Note that the positive electrode 201 of the battery 200 and the connection terminal Nd1, as well as the negative electrode terminal 202 of the battery and the connection terminal Nd2 are each connected by wire.

In the battery module 300, the connection terminal Nd1 and the connection terminal Nd2 of the semiconductor device 100 is supplied with the supply voltage from the battery 200. In this case, the potential of the connection terminal Nd1 is higher than the potential of the connection terminal Nd2 by the supply voltage.

The low-voltage side frame 1 is made of a plate material having conductivity similarly to the high-voltage side frame 3. The connection terminal Nd5 and the connection terminal Nd17 are formed integrally with the low-voltage side frame 1. The low-voltage side frame 1 is connected to the ground potential GND via the connection terminal Nd5 and the connection terminal Nd17. Note that it may be possible to adopt a structure in which the connection terminal Nd5 and the connection terminal Nd17 are disposed apart from the low-voltage side frame 1, and the connection terminal Nd5 and the connection terminal Nd17 are each connected to the low-voltage side frame 1 by wire. As long as the connection terminal Nd5 and the connection terminal Nd17 are securely connected to the low-voltage side frame 1, the connection method is not limited.

Further, the connection terminal Nd6 to the connection terminal Nd16 are each connected to the low-voltage chip 2, which is connected to the low-voltage side frame 1, via the wire 5 having conductivity.

The low-voltage side frame 1 is configured to be insulated from the high-voltage side frame 3. More specifically, the low-voltage side frame 1 and the high-voltage side frame 3 are not electrically connected to each other and are disposed apart from each other in such a degree that when noise occurs in one frame, the other frame is not affected by the noise.

In the semiconductor device 100 of the present disclosure, the low-voltage side frame 1 and the high-voltage side frame 3 are insulated from each other, but reference potentials of them are both the ground potential GND.

The low-voltage chip 2 is connected to the low-voltage side frame 1 so as to be connected to the ground potential GND. In other words, the ground potential GND is the reference potential of the low-voltage chip 2.

As illustrated in FIG. 3, an input voltage Vin is input to the low-voltage chip 2, which is driven by the input voltage Vin. The input voltage Vin is a voltage for driving a circuit of the semiconductor device 100 and is supplied from a not-shown voltage source. Note that it may be possible to adopt a structure in which a battery other than the battery 200 is used as the voltage source, or it may be possible to adopt a structure including a power supply circuit that steps down the supply voltage of the battery 200.

The low-voltage chip 2 is supplied with the operating voltage Vs from the high-voltage chip 4. The operating voltage Vs is one of output voltages output to the outside of the semiconductor device 100 and is a voltage for driving a circuit included in the motor control unit 500 in the electric power module 600 of the present disclosure. The semiconductor device 100 also outputs a first checking voltage Vc1, a second checking voltage Vc2, and a check voltage PNVOUT, which are used by the motor control unit 500 to detect the supply voltage applied to the high-voltage chip 4. In addition, it also outputs a voltage Vft for checking an operating state of the semiconductor device 100.

The low-voltage chip 2 is an amplifier chip having a structure including an under voltage lock out (UVLO) circuit 21, an inspection circuit 22, a constant voltage circuit 23, a check amplifier 24, and a fault signal output circuit 25. As illustrated in FIG. 2, the low-voltage chip 2 is connected to the connection terminal Nd6 to the connection terminal Nd16. The low-voltage chip 2 and each connection terminal are connected to each other, when the pad 26 disposed on an outer surface of the low-voltage chip 2 and the connection terminal are connected by the wire 5.

The semiconductor device 100 has its specification in which an appropriate voltage range is specified for the input voltage Vin. The UVLO circuit 21 compares the input voltage Vin with a predetermined UVLO determination voltage lower than the lower limit of the voltage range, and outputs an UVLO signal Sv. The UVLO signal Sv is high level when the input voltage Vin is lower than or equal to the UVLO determination voltage, and otherwise it is low level. The state where the input voltage Vin is lower than or equal to the UVLO determination voltage is a low voltage abnormality state in which the input voltage Vin is too low. In other words, in the low voltage abnormality state, the UVLO circuit 21 outputs the UVLO signal Sv of high level.

The inspection circuit 22 is connected to the connection terminals Nd15 and Nd16, which are connected to the ground potential GND, and compares the ground potential GND input from each of the connection terminals Nd15 and Nd16 with a threshold value, so as to output a TEST signal St. Further, the inspection circuit 22 is configured so that the TEST signal St becomes high level, if at least one of the signals input from the connection terminals Nd15 and Nd16 is high level.

The constant voltage circuit 23 is a circuit that generates a voltage to be output to the outside of the semiconductor device 100. The constant voltage circuit 23 can generate a voltage different from the input voltage Vin. The voltage generated in the constant voltage circuit 23 is input to the check amplifier 24.

The noninverting input terminal (+) of the check amplifier 24 is supplied with the first checking voltage Vc1 that is supplied from a connection node P2, whose potential is higher than a potential of a connection node P1 connected to a voltage dividing terminal 42 described later of the high-voltage chip 4. In addition, the inverting input terminal (−) is supplied with the second checking voltage Vc2 that is supplied from a connection node P3, whose potential is lower than a potential of the connection node P1 connected to the voltage dividing terminal 42. Here, the first checking voltage Vel is a voltage higher than the operating voltage Vs by a voltage of a resistor 41 described later of the high-voltage chip 4. In addition, the second checking voltage Vc2 is a voltage lower than the operating voltage Vs by the voltage of the resistor 41.

The check amplifier 24 compares the first checking voltage Vel with the second checking voltage Vc2, so as to output its result as the check voltage PNVOUT. The semiconductor device 100 illustrated in FIG. 3 has a structure in which the check voltage PNVOUT is output to the connection terminal Nd12. The check voltage PNVOUT is disturbed when noise is superimposed on at least one of the first checking voltage Vc1 and the second checking voltage Vc2. Further, the motor control unit 500 measures disturbance of the check voltage PNVOUT, and hence it can determine whether or not the operating voltage Vs is output stably.

In the semiconductor device 100 of the present disclosure, the first checking voltage Vc1, the check voltage PNVOUT, and the second checking voltage Vc2 are respectively output to the connection terminals Nd11, Nd12, and Nd13 (see FIG. 3).

The connection terminals Nd11, Nd12, and Nd13 are each connected to the ground potential GND via a resistor and a capacitor. Further, voltages at the connection nodes of the resistors and the capacitors connected to the connection terminals Nd11, Nd12, and Nd13 are input to the motor control unit 500. On the basis of these voltages, the motor control unit 500 determines states of the first checking voltage Vel, the check voltage PNVOUT, and the second checking voltage Vc2, and detects the supply voltage applied to the high-voltage chip 4.

The fault signal output circuit 25 includes an OR circuit 251 and the switching element 252. The OR circuit 251 is supplied with the UVLO signal Sv and the TEST signal St. The OR circuit 251 outputs a fault signal Sft on the basis of the UVLO signal Sv and the TEST signal St. The switching element 252 is an n-channel type MOS transistor in this description. The drain of the switching element 252 is connected to the connection terminal Nd6. The connection terminal Nd6 is connected to the input voltage Vin via a resistor.

In addition, the source of the switching element 252 is connected to the ground potential GND. The gate of the switching element 252 is supplied with the fault signal Sft. When the fault signal Sft is low level, the switching element 252 is controlled to be OFF. In this case, the connection terminal Nd6 has a potential of high level. In addition, when the fault signal Sft is high level, the switching element 252 is controlled to be ON, and the connection terminal Nd6 has a potential of low level. The connection terminal Nd6 is connected to the motor control unit 500, and the motor control unit 500 is supplied with the voltage Vft based on the potential of the connection terminal Nd6.

If no abnormality is found in the UVLO circuit 21 and the inspection circuit 22, the UVLO signal Sv and the TEST signal St are both low level, and the OR circuit 251 of the fault signal output circuit 25 outputs the fault signal Sft of low level. As a result, the switching element 252 is controlled to be OFF, and in this case, the connection terminal Nd6 has a potential of high level.

On the other hand, if an abnormality is found in at least one of the UVLO circuit 21 and the inspection circuit 22, at least one of the UVLO signal Sv and the TEST signal St is high level, and the OR circuit 251 of the fault signal output circuit 25 outputs the fault signal Sft of high level. As a result, the switching element 252 is controlled to be ON, and the potential at the connection terminal Nd6 becomes low level.

The motor control unit 500 determines that no abnormality has occurred in the semiconductor device 100 if the voltage Vft is high level, while it determines that an abnormality has occurred if the same is low level. Note that it may be possible to configure so that the motor control unit 500 determines an abnormality of the low-voltage chip 2 on the basis of the connection terminal Nd6.

Note that the switching element 252 may be a p-channel type MOS transistor without limited to an n-channel type MOS transistor. In this case, a potential level of the connection terminal Nd6 of the switching element 252 due to the fault signal Sft is inverted from that in the case of the n-channel type MOS transistor. In other words, when the fault signal Sft of low level is input, the switching element 252 becomes ON state, and the potential of the connection terminal Nd6 becomes low level. When the fault signal Sft is other than that, the potential of the connection terminal Nd6 becomes high level. For this reason, the abnormality determination by the motor control unit 500 on the basis of the voltage Vft is opposite to that in the case where the n-channel type MOS transistor is used.

Although the structure of the low-voltage chip 2 is described above, in an actual circuit, in many cases, circuits and elements other than the above circuits and elements are wired. For instance, if a switching element that is switched at high speed is included, switching noise may be superimposed on the low-voltage side frame 1 connected to the low-voltage chip 2 and the low-voltage chip 2. The high-voltage side frame 3 is hardly affected by the switching noise because it is insulated from the low-voltage side frame 1.

The high-voltage chip 4 is a resistor chip including the eight resistors 41. The eight resistors 41 are connected in series. The high-voltage chip 4 is connected to the connection terminal Nd1 and the connection terminal Nd2. Note that the high-voltage side frame 3 is configured not to be directly connected to the connection terminal Nd1 and the connection terminal Nd2.

The connection terminal Nd1 is connected to a first terminal of the resistors 41 connected in series in the high-voltage chip 4, and the connection terminal Nd2 is connected to a second terminal of the resistors 41 connected in series. In this way, the supply voltage is applied between both terminals of the high-voltage chip 4 via the connection terminal Nd1 and the connection terminal Nd2.

In other words, the supply voltage is applied between both terminals of the plurality of resistors 41 connected in series in the high-voltage chip 4. Further, the high-voltage chip 4 includes the voltage dividing terminal 42 that divides the supply voltage so as to output a predetermined voltage. Among connection nodes between the resistors 41, the voltage dividing terminal 42 is connected to a connection node that can divide the supply voltage into a desired voltage. In the high-voltage chip 4 of the present disclosure, the voltage dividing terminal 42 is connected to the connection node P1 between the forth resistor 41 and the fifth resistor 41 from the connection terminal Nd1 side. The voltage dividing terminal 42 divides the supply voltage by the combined resistance of the resistors 41 on the connection terminal Nd1 side than the voltage dividing terminal 42, and the combined resistance of the resistors 41 on the connection terminal Nd2 side than the same.

The high-voltage chip 4 is connected to the high-voltage side frame 3. The high-voltage chip 4 is connected to the high-voltage side frame 3, so that a potential at one of the connection nodes between the resistors 41 is connected to the high-voltage side frame 3 to be the reference potential. In the high-voltage chip 4 of the semiconductor device 100 of the present disclosure, a connection node P0 of the resistor 41 connected to the connection terminal Nd2 is connected to the reference potential.

As described above, the battery 200 is configured to apply a voltage to the circuit so that the positive electrode 201 has a potential difference corresponding to the supply voltage with respect to the negative electrode 202. In the semiconductor device 100 of the present disclosure, the positive electrode 201 is connected to the first terminal of the high-voltage chip 4, while the negative electrode 202 is connected to the second terminal of the same, and the connection node P0 as the second terminal is the ground potential GND as the reference potential. In this way, the potential of the voltage dividing terminal 42 is an operating potential Vps, which has the potential difference corresponding to the divided voltage by the resistors 41 of the high-voltage chip 4 from the ground potential GND.

The voltage dividing terminal 42 is connected to the connection terminal Nd10, and the potential of the connection terminal Nd10 is the operating potential Vps. The connection terminal Nd10 is connected to the ground potential via a resistor and a capacitor, and in the semiconductor device 100, the operating voltage Vs based on the potential at the connection node between the resistor and the capacitor, which are connected to the connection terminal Nd10, is supplied to the motor control unit 500.

In the semiconductor device 100 of the present disclosure, the voltage dividing terminal 42 is connected to the connection terminal Nd10 via a circuit inside the low-voltage chip 2. Further, the low-voltage chip 2 may have a circuit configured to be capable of monitoring the operating potential Vps at the voltage dividing terminal 42. In this way, for example, the low-voltage chip 2 can detect that the battery 200 is in a state where the supply voltage is decreased or in an over-discharge state. Further, the low-voltage chip 2 may inform the motor control unit 500 of the detection result or may have a circuit configured to voluntarily stop supplying power to the outside. In addition, the voltage dividing terminal 42 may be directly connected to the connection terminal Nd10 without the low-voltage chip 2.

As described above, in the semiconductor device 100, the first checking voltage Vc1 and the second checking voltage Vc2 are output from the high-voltage chip 4. The first checking voltage Vc1 is output, on the basis of the potential at the connection node P2 between the third resistor 41 and the fourth resistor 41 from the connection terminal Nd1 side. In addition, the second checking voltage Vc2 is output, on the basis of the potential at the connection node P3 between the fifth resistor 41 and the sixth resistor 41 from the connection terminal Nd1 side. In the semiconductor device 100 of the present disclosure, the forth resistor 41 and the fifth resistor 41 from the connection terminal Nd1 side have the same resistance value.

Note that in the high-voltage chip 4, a resistance value of each of the resistors 41 is determined so that required voltages can be stably output. Note that resistance values of the plurality of resistors 41 may be the same resistance value or may be difference resistance values. In addition, the number of the resistor 41 is not limited to eight.

In the high-voltage chip 4, by changing at least one of the connection node between the resistors 41, to which the voltage dividing terminal 42 is connected, and the connection node between the resistors 41, to which the high-voltage side frame 3 is connected, the operating voltage Vs can be changed. Note that the high-voltage chip 4 may be configured to include a plurality of the voltage dividing terminals 42, so as to be capable of supplying voltages having different voltage values. The semiconductor device 100 have the schematic structure described above.

In the semiconductor device 100 of the present disclosure, the high-voltage chip 4 is configured so that one terminal of the resistors 41 connected in series is the ground potential as the reference potential, but this is not a limitation. For instance, the connection node between the first resistor 41 and the second resistor 41 from the connection terminal Nd2 side may be connected to the reference potential. In this case, the potential difference between the connection terminal Nd1 and the connection terminal Nd2 is the supply voltage, and the potential at the connection terminal Nd2 is lower than the reference potential by the voltage drop of the first resistor 41 from the connection terminal Nd2 side. As a result, the potential at the voltage dividing terminal 42 is also lower in the same manner. In this way, also by changing the terminal to be the reference potential, the potential of the voltage dividing terminal 42 and the operating voltage Vs output from the voltage dividing terminal 42 can be changed.

The semiconductor device 100 is sealed in the package Pg made of resin, for example. As illustrated in FIG. 4, in the semiconductor device 100, the high-voltage chip 4 is disposed on the top surface of the high-voltage side frame 3. For this reason, the underside of the high-voltage chip 4 as a first surface 4d contacts the high-voltage side frame 3, and a specific connection node of the high-voltage chip 4 is connected to the high-voltage side frame 3.

In the semiconductor device 100, the wire 5, which connects the high-voltage chip 4 and each of the connection terminal Nd1 and the connection terminal Nd2, is connected to the pad 43 exposed on the top surface of the high-voltage chip 4, which is a second surface 4u opposite to the first surface 4d in the thickness direction. Further, the wire 5 is held by the resin forming the package Pg. As a result, the wire 5 does not contact the high-voltage side frame 3. In other words, the supply voltage supplied via the connection terminal Nd1 and the connection terminal Nd2 is not supplied to the high-voltage side frame 3 but is supplied only to the high-voltage chip 4.

In other words, the high-voltage side frame 3 is insulated from the connection terminal Nd1 and the connection terminal Nd2. In this way, even if noise is superimposed on the positive electrode 201 and the negative electrode 202 of the battery 200, the reference potential of the high-voltage side frame 3 is hardly affected by the noise. As the potential of the voltage dividing terminal 42 is stable, the operating voltage Vs having a stable voltage is output.

In addition, a plurality of switching elements may be mounted on the low-voltage chip 2 connected to the low-voltage side frame 1. When the switching element is controlled to switch at high speed, switching noise may occur on the low-voltage side frame 1. As the high-voltage side frame 3 is insulated from the low-voltage side frame 1, the reference potential of the high-voltage side frame 3 is not affected by the switching noise that has occurred on the low-voltage side frame 1. For this reason, the voltage output from the high-voltage chip 4 can be immune to the noise that has occurred in the low-voltage chip 2.

As described above, having the structure of the semiconductor device 100, the motor control unit 500 can obtain the supply voltage of the battery 200 on the basis of the operating voltage Vs having a stable voltage, and hence can obtain an accurate value of the battery 200, so as to be capable of enhancing accuracy in driving the motor 400.

Note that, as the noise superimposed on the potential of the low-voltage side frame 1, noise other than the switching noise may occur. As the high-voltage side frame 3 is insulated from the low-voltage side frame 1, the reference potential of the high-voltage side frame 3 is hardly affected by any noise that occurs on the low-voltage side frame 1 and the low-voltage chip 2. In other words, the output supplied from the high-voltage chip 4 is hardly affected by noise that occurs in the low-voltage chip 2 and can be output with a stable voltage.

### Modified Example

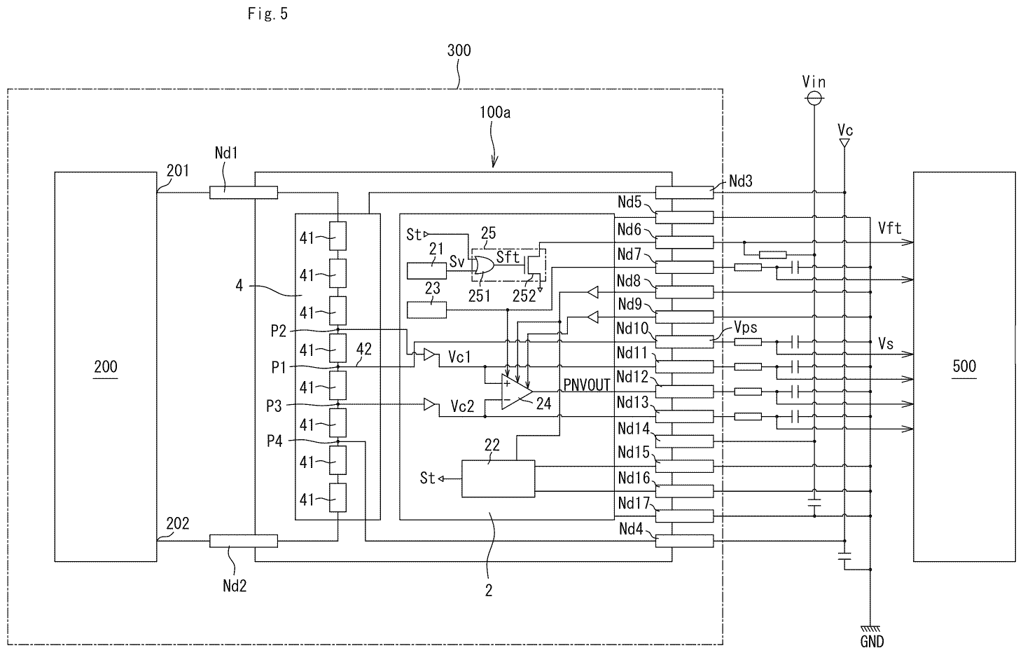

FIG. 5 is a diagram illustrating a schematic structure of a semiconductor device 100a of the modified example. In the semiconductor device 100a illustrated in FIG. 5, the reference potential and the connection node to which the reference potential is given are different from those in the semiconductor device 100 illustrated in FIG. 1. Other structural points of the semiconductor device 100a are the same as those of the semiconductor device 100. For this reason, a section of the semiconductor device 100a that is substantially the same as that of the semiconductor device 100 is denoted by the same numeral or symbol, and detailed description of the same section is omitted.

In the semiconductor device 100a illustrated in FIG. 5, the connection terminal Nd3 and the connection terminal Nd4 are connected to a first reference potential Vc having a stable potential difference with respect to the ground potential GND. Further, the connection terminal Nd3 and the connection terminal Nd4 are connected to the high-voltage side frame 3 similarly to the semiconductor device 100. In this way, the reference potential of the high-voltage side frame 3 is the first reference potential Vc.

Further, in the high-voltage chip 4a, the connection node P4 between the second resistor 41 and the third resistor 41 from the connection terminal Nd2 side is connected to the high-voltage side frame 3, the potential at the connection node P4 of the high-voltage chip 4a is the first reference potential Ve as the reference potential. In this way, in the semiconductor device 100a, the operating voltage Vs, which is the same as that in the semiconductor device 100 whose reference potential is the ground potential GND, is output from the voltage dividing terminal 42.

Note that it is preferred that the potential difference between the first reference potential Vc and the ground potential GND be smaller than the input voltage Vin. However, the first reference potential Vc is not limited to the above description, but various stable potentials can be adopted in a device in which the semiconductor device 100 is mounted.

### Others

The above embodiment is merely an example in every aspect and should not be interpreted as a limitation. The technical scope of the present invention is defined not by the above description of the embodiment but by the claims and should be understood to include all modifications within meanings and scopes equivalent to the claims.

A semiconductor device (100), which is described above, has a structure (first structure) including a low-voltage side frame (1) configured to be connected to a low-voltage chip (2) driven by an input voltage (Vin) and connected to a ground potential (GND); and a high-voltage side frame (3) configured to be insulated from the low-voltage side frame (1) and connected to a high-voltage chip (4) supplied with a supply voltage having a higher voltage than the input voltage (Vin). The high-voltage side frame (4) is connected to a reference potential.

In the semiconductor device (100) having the above first structure, there is a structure (second structure) in which the high-voltage chip (4) is a resistor chip configured to include a plurality of resistors (41) connected in series, and the low-voltage chip (2) is constituted of an amplifier chip on which an electronic component is mounted.

In the semiconductor device (100) of the above first or second structure, there is a structure (third structure) in which the high-voltage chip (4) has a first surface (4d) connected to the high-voltage side frame, and the supply voltage is supplied to a second surface (4u) opposite to the first surface (4d) in a thickness direction.

In the semiconductor device (100) of any one of the above first to third structures, there is a structure (fourth structure) in which the reference potential is the ground potential (GND).

In the semiconductor device (100a) of any one of the above first to third structures, there is a structure (fifth structure) in which a potential difference between the reference potential (Vs) and the ground potential (GND) is equal to the input voltage (Vin).

In the semiconductor device (100, 100a) of any one of the above first to fifth structures, there is a structure (sixth structure) in which the low-voltage side frame (1) and the high-voltage side frame (3) are formed integrally with connection terminals (Nd5, Nd17, Nd3, Nd4) connected to the reference potential, and the connection terminal (Nd5, Nd17) formed integrally with the low-voltage side frame (1) is insulated from the connection terminal (Nd3, Nd4) formed integrally with the high-voltage side frame (3).

In the semiconductor device (100, 100a) of any one of the above first to sixth structures, there is a structure (seventh structure) in which the high-voltage side frame (3) is insulated from a terminal (Nd1, Nd2) supplying the supply voltage to the high-voltage chip (4).

In the semiconductor device (100, 100a) of any one of the above first to seventh structures, there is a structure (eighth structure) in which at least the low-voltage side frame (1), the low-voltage chip (2), the high-voltage side frame (3), and the high-voltage chip (4) are included in a package (Pg) sealed with resin.

A battery module (300), which includes the semiconductor device (100, 100a) of any one of the above first to eighth structures, has a structure (ninth structure) including a battery (200) configured to be capable of supplying the supply voltage to the high-voltage chip (4).

An electric power module (600) has a structure (tenth structure) including the battery module (300) of the above ninth structure, and a drive source (400) configured to be supplied with power from the battery module (300).

An electric vehicle (A) has a structure (eleventh structure) including the electric power module (600) of the above tenth structure.

### LIST OF REFERENCE SIGNS

A electric vehicle
Ax axle shaft
Wh wheel
100, 100a semiconductor device
200 battery
201 positive electrode
202 negative electrode
300 battery module
400 motor
500 motor control unit
600 electric power module
1 low-voltage side frame
2 low-voltage chip
21 UVLO circuit
22 inspection circuit
23 constant voltage circuit
24 check amplifier
25 fault signal output circuit
251 OR circuit
252 switching element
26 pad
3 high-voltage side frame
4, 4a high-voltage chip
4d first surface
4u second surface
41 resistor
42 voltage dividing terminal
43 pad
5 wire
Nd1 to Nd17 connection terminal
P0 to P4 connection node
Pg package

1. A semiconductor device comprising:
a low-voltage side frame configured to be connected to a low-voltage chip driven by an input voltage and connected to a ground potential; and
a high-voltage side frame configured to be insulated from the low-voltage side frame and connected to a high-voltage chip supplied with a supply voltage having a higher voltage than the input voltage, wherein
the high-voltage side frame is connected to a reference potential.

2. The semiconductor device according to claim 1, wherein
the high-voltage chip is a resistor chip configured to include a plurality of resistors connected in series, and
the low-voltage chip is constituted of an amplifier chip on which an electronic component is mounted.

3. The semiconductor device according to claim 1, wherein the high-voltage chip has a first surface connected to the high-voltage side frame, and the supply voltage is supplied to a second surface opposite to the first surface in a thickness direction.

4. The semiconductor device according to claim 1, wherein the reference potential is the ground potential.

5. The semiconductor device according to claim 1, wherein a potential difference between the reference potential and the ground potential is equal to the input voltage.

6. The semiconductor device according to claim 1, wherein
the low-voltage side frame and the high-voltage side frame are formed integrally with connection terminals connected to the reference potential, and
the connection terminal formed integrally with the low-voltage side frame is insulated from the connection terminal formed integrally with the high-voltage side frame.

7. The semiconductor device according to claim 1, wherein the high-voltage side frame is insulated from a connection terminal that supplies the supply voltage to the high-voltage chip.

8. The semiconductor device according to claim 1, wherein at least the low-voltage side frame, the low-voltage chip, the high-voltage side frame, and the high-voltage chip are included in a package sealed with resin.

9. A battery module comprising:
the semiconductor device according to claim 1; and
a battery configured to be capable of supplying the supply voltage to the high-voltage chip.

10. An electric power module comprising:
the battery module according to claim 9; and
a drive source configured to be supplied with power from the battery module.

11. An electric vehicle comprising the electric power module according to claim 10.
